(19) United States
(12) Patent Application Publication
(10) Pub. No.: US 2026/0331909 A1
(43) Pub. Date: Oct. 22, 2026

(54) ENHANCED SURGE PROTECTION DEVICE

(71) Applicant: viaPhoton, Inc., Naperville, IL (US)

(72) Inventors: Mark James Smrha, Chicago, IL (US); Walter Mark Hendrix, Dallas, TX (US); Steve Fischer, Windsor, CO (US)

(21) Appl. No.: 19/529,480

(22) Filed: Feb. 4, 2026

Related U.S. Application Data
(60) Provisional application No. 63/753,778, filed on Feb. 4, 2025.

(51) Int. Cl. H02H 9/04; H01C 7/12; H02H 1/00; H02H 1/06

(52) U.S. Cl. CPC H02H 9/042; H01C 7/12; H02H 1/0076; H02H 1/06; H02H 9/045

(57) ABSTRACT

An enhanced surge protection system includes an SPD state monitor coupled to a conductor pair extending to a remote installation location having multiple surge protection devices (SPDs). The SPD state monitor generates interrogation signals at different interrogation frequencies, couples the interrogation signals into the conductor pair via an exciter configured for electromagnetic coupling, and senses return signals via a reactor configured for electromagnetic sensing. Respective SPDs include frequency-selective networks that present different impedance responses as a function of interrogation frequency, enabling determination of an SPD identity and an operating state based on the interrogation frequency and a return-signal magnitude. A corresponding SPD includes terminals for the conductor pair, a surge suppression stage, a frequency-selective network, and a state-encoding circuit that alters a return characteristic responsive to a condition of the surge suppression stage. A corresponding method performs the interrogation, sensing, determination, and outputting.

### CROSS REFERENCE TO RELATED APPLICATIONS

This Application claims the benefit of U.S. Provisional Application Ser. No. 63/753,778, filed Feb. 4, 2026, and entitled “ENHANCED SURGE PROTECTION DEVICE,” which is hereby incorporated by reference for all purposes.

### BACKGROUND

Surge protection devices are commonly deployed in telecommunications infrastructure to reduce the likelihood of equipment damage and service interruption caused by lightning, switching transients, and other overvoltage events. In a typical cell site, surge protection may be provided at multiple physical locations, including equipment cabinets at ground level and enclosures located near radio equipment mounted on a tower. Such installations often involve long conductor runs between tower-mounted equipment and base equipment, and those conductor runs can present multiple surge entry paths as well as differing impedance and grounding environments across the site.

Operators and integrators frequently seek visibility into the operational condition of installed surge protection devices so that maintenance can be scheduled and failed devices can be replaced before protection is lost. Conventional approaches include local status indicators, dry-contact alarms, and supervisory monitoring circuits that report whether a protection element has opened, shorted, or otherwise transitioned to a fault condition. In many deployments, status monitoring requires additional wiring to each surge protection device, the use of dedicated input channels at a monitoring unit, or the installation of additional powered electronics at locations where only passive protection hardware was previously deployed.

These monitoring approaches can introduce integration and reliability issues in the field. Adding dedicated conductors and alarm channels increases wiring complexity and termination labor, particularly at tower tops and other constrained locations. Monitoring conductors may also couple noise or transient energy into sensitive inputs, and differences in grounding and bonding practices across sites can lead to inconsistent alarm behavior. Further, some status schemes provide only a binary indication that a device has failed, which can limit the ability to plan preventive maintenance and can result in either premature replacement or extended operation with reduced protection margin.

### SUMMARY

The embodiments herein provide for an enhanced surge protection system that includes an SPD state monitor coupled to a conductor pair that extends to a remote installation location at which a plurality of surge protection devices is coupled. The SPD state monitor applies interrogation signals at multiple interrogation frequencies via an exciter that electromagnetically couples the interrogation signals into the conductor pair, and a reactor electromagnetically senses corresponding return signals associated with the conductor pair. Different surge protection devices include corresponding frequency-selective networks that present different impedance responses as a function of interrogation frequency, and the SPD state monitor determines, based on at least one of interrogation frequency and a return-signal magnitude, an identity and an operating state of at least one surge protection device.

In one or more embodiments, a surge protection device is configured for use in a frequency-interrogated surge protection system and includes terminals for coupling to a conductor pair, a surge suppression stage coupled to the terminals, and a frequency-selective network coupled to the terminals. The frequency-selective network is configured to present, at a selected interrogation frequency assigned to the surge protection device, a first impedance different than a second impedance presented at at least one other interrogation frequency. The surge protection device further includes a state-encoding circuit configured to alter, responsive to a condition of the surge suppression stage, a return characteristic presented to the conductor pair such that an SPD state monitor can distinguish at least two operating states of the surge protection device based on a sensed return magnitude.

In one or more embodiments, a method for remotely identifying and monitoring surge protection devices includes coupling an SPD state monitor to a conductor pair extending to a remote installation location at which a plurality of surge protection devices are coupled to the conductor pair. The method includes generating, with the SPD state monitor, a sequence of interrogation signals at different interrogation frequencies, inductively coupling the interrogation signals into the conductor pair using an exciter, and sensing return signals using a reactor inductively coupled to the conductor pair. The method further includes determining, based on at least one sensed return magnitude associated with at least one interrogation frequency, an identity of at least one surge protection device and an operating state of the at least one surge protection device, and outputting an indication of the identity and the operating state to a downstream interface.

Other aspects of the invention will be apparent from the following description and the appended claims.

### BRIEF DESCRIPTION OF DRAWINGS

FIG. 1 is a cell-site installation environment in accordance with one or more embodiments of the disclosure.

FIGS. 2A and 2B show an example top-enclosure in accordance with one or more embodiments of the disclosure.

FIGS. 3A and 3B illustrate an example base-enclosure in accordance with one or more embodiments of the disclosure.

FIG. 4 is a functional block diagram of an example monitoring arrangement in accordance with one or more embodiments of the disclosure.

FIG. 5A is a diagram of a surge protection device in accordance with one or more embodiments of the disclosure.

FIG. 5B is an example non-harmonic table of interrogation frequencies in accordance with one or more embodiments of the disclosure.

FIG. 6 is a flowchart in accordance with one or more embodiments of the disclosure.

FIGS. 7A and 7B show a computing system in accordance with one or more embodiments of the invention.

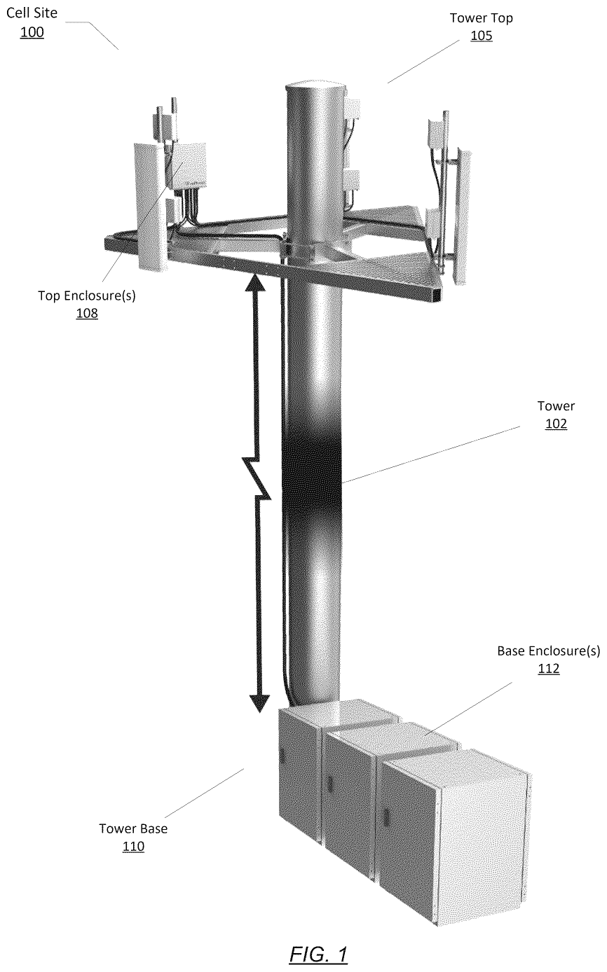

Like elements in the various figures are denoted by like reference numerals for consistency.

### DETAILED DESCRIPTION

In general, embodiments are directed to an enhanced surge protection architecture in which surge protection devices are distributed across physically separated locations, including tower-top and tower-base regions of a cell site. A conductor pair extending between the locations is used not only as a protected path for operational conductors, but also as a signaling medium by which installed surge protection devices can be remotely identified and monitored from a monitoring location. The architecture supports installations in which multiple surge protection devices are associated with a shared conductor pair, with device identification achieved by distinguishing responses to interrogation frequencies that are assigned per device or per internal channel.

In one or more embodiments, a monitoring process applies interrogation signals to the conductor pair via electromagnetic coupling and senses resulting return behavior using electromagnetic sensing, thereby maintaining galvanic isolation between monitoring electronics and the conductor pair. Surge protection devices can incorporate frequency-selective networks that present frequency-dependent impedance responses, enabling the monitoring process to associate a detected response with a device identity and to infer an operating state based on measured return characteristics. The operating state can be represented as a multi-state model that distinguishes at least a normal condition, a degraded condition associated with reduced protective margin, and a critical failure condition associated with a short or low-impedance condition on the conductor pair, thereby supporting maintenance decisions beyond binary “good/bad” reporting.

In one or more embodiments, degradation reporting is supported by configurations in which surge suppression circuitry includes multiple suppression elements arranged to exhibit staged end-of-life behavior, enabling the monitoring process to detect a degradation state before the site loses primary surge protection. The monitoring outputs can be provided through a device interface to downstream systems for logging, alarming, or network reporting, and the interrogation sequence may be repeated at predetermined intervals to provide updated state information over time without requiring manual inspection at the remote installation location.

A cell site (100) includes an installation environment in which surge protection devices are deployed at physically separated locations and are coupled by cabling routed along a tower. In the illustrated arrangement, at least a portion of the protected conductor paths extend between equipment located proximate to a tower top (105) and equipment located proximately to a tower base (110), such that surge suppression and monitoring functions may be distributed across the site.

A tower (102) supports tower-top equipment and provides a routing structure for conductor paths extending between the tower top (105) and the tower base (110). In use, the tower (102) carries one or more conductor runs routed downward from the tower top (105) toward the tower base (110), and the conductor runs may serve as both protected conductors and as a conductive medium through which operating state information for surge protection devices can be interrogated and observed from a remote location.

The tower top (105) represents a tower-mounted region of the cell site (100) at which equipment and enclosures are positioned in proximity to radio hardware. In the illustrated arrangement, the tower top (105) is associated with one or more elevated mounting structures and conductor routing features, and cabling is shown routed between multiple tower-top devices and toward the tower (102) for descent to the tower base (110).

One or more top enclosures (108) are positioned at or proximate the tower top (105) and define an enclosed volume for housing tower-top components associated with protected conductor paths. In some embodiments, at least one top enclosure (108) houses a tower-top surge protection device (TT-SPD) that is coupled to one or more conductor paths routed between tower-top equipment and tower-base equipment. The top enclosure(s) (108) provides an interface location at which conductor paths enter and exit the enclosure, and the conductor paths are routed from the enclosure toward the tower (102) for descent to the tower base (110).

The tower base (110) represents a ground-level region of the cell site (100) at which equipment cabinets and enclosures are positioned and at which tower-routed cabling terminates or is redistributed. In use, conductor paths routed down the tower (102) from the tower top (105) are received proximate to the tower base (110) and may be coupled to additional equipment, including base-located surge protection devices and monitoring components.

One or more base enclosures (112) are positioned at or proximate the tower base (110) and define an enclosed volume for housing base-located components associated with protected conductor paths. In some embodiments, at least one base enclosure (112) houses a tower-base surge protection device (TB-SPD) that is coupled to the same conductor path as a corresponding TT-SPD housed at the tower top (105), thereby providing distributed surge suppression along the tower-routed conductor run. In further embodiments, a monitoring component located at or near the base enclosure(s) (112) is configured to interrogate the conductor path and to determine an operating state of one or more surge protection devices at the tower top (105) and/or the tower base (110) based on electrical behavior observed on the conductor path.

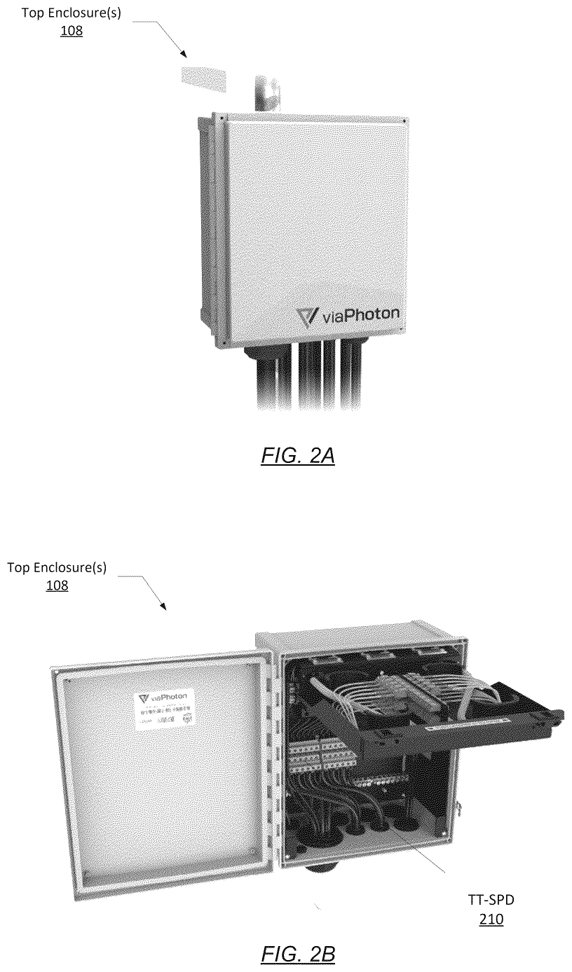

FIGS. 2A and 2B show the top enclosure(s) (108) in a closed configuration and in an opened configuration. FIGS. 2A and 2B illustrate a tower-top installation volume for components associated with tower-top equipment located at the tower top (105). In use, the top enclosure(s) (108) are positioned along a tower-mounted structure and receive one or more conductor runs that extend along the tower (102) toward the tower base (110).

The top enclosure(s) (108) includes a housing defining an interior volume and a cover coupled to the housing to provide access to the interior volume. The cover is movable between a closed position in which the interior volume is enclosed and an open position in which the interior volume is exposed for installation, routing, or servicing of internal components. Internal mounting regions and routing space provide for conductor runs that enter the enclosure and are guided to internal termination or interconnection locations.

A cable entry region of the top enclosure(s) (108) receives conductor runs routed from tower-top equipment and/or routed toward the tower base (110). In the illustrated arrangement, multiple conductor segments extend from the enclosure, and the conductor segments may include power conductors, signal conductors, or other conductors associated with tower-top equipment. The conductor segments are routed through entry features at the enclosure boundary, and the conductor segments are guided within the interior volume toward internal components.

The top enclosure(s) (108) further includes internal interface hardware positioned to organize conductor terminations and interconnections within the interior volume. The illustrated arrangement depicts an internal panel region and a movable tray region supporting connectorized terminations, with routed jumper conductors extending between connector fields and interior components. The tray region is shown displaced outward from the housing to provide access to connector faces and to create routing space for bend management and strain relief within the enclosure.

A tower-top surge protection device (TT-SPD) (210) is disposed within the interior volume of the top enclosure(s) (108) and is coupled to at least one conductor path associated with tower-top equipment. The TT-SPD (210) is positioned such that conductors entering the top enclosure(s) (108) can be coupled through, or electrically associated with, the TT-SPD (210) prior to being routed onward to other tower-top components and/or toward the tower base (110).

In an embodiment, the TT-SPD (210) is an internal assembly located within the enclosure volume and arranged relative to the internal routing space so that conductor segments can be routed between the cable entry region and the internal interface hardware while remaining electrically coupled to surge suppression circuitry of the TT-SPD (210). The TT-SPD (210) may be implemented as a modular unit, a board-mounted assembly, or another packaged form factor supported within the enclosure, with electrical coupling established via conductors, terminals, harnesses, or interconnection features located within the top enclosure(s) (108).

The TT-SPD (210) is further arranged for cooperative operation with remote monitoring equipment located away from the tower top (105), such that the electrical behavior presented by the TT-SPD (210) on an associated conductor pair can be interrogated and used to determine an operating state of the TT-SPD (210). In this configuration, the top enclosure(s) (108) provides a defined physical location for the TT-SPD (210) at the tower top (105) while enabling conductor runs extending along the tower (102) to serve as the coupling medium between the TT-SPD (210) and tower-base monitoring components.

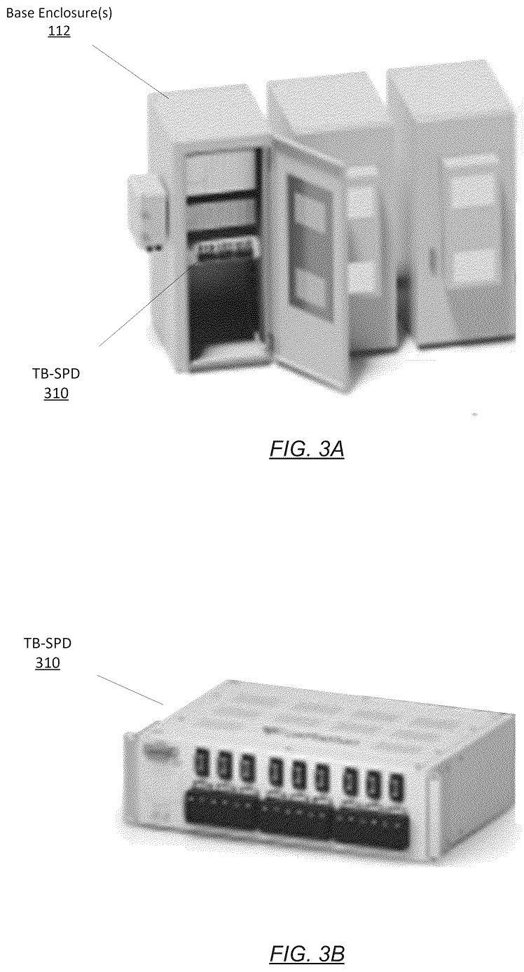

FIGS. 3A and 3B illustrate a tower-base surge protection device (TB-SPD) (310) in association with one or more base enclosures (112) at a cell site (100). In the illustrated environment, equipment at the tower base (110) is supported within, or in association with, the base enclosures (112), and cabling extends between the tower base (110) and tower top (105) of the tower (102).

In FIG. 3A, the base enclosure(s) (112) are shown as a tower-base installation location for components associated with monitoring and protecting conductors that route between the tower base (110) and equipment positioned at the tower top (105). The base enclosure(s) (112) can provide mounting volume and environmental separation for devices that interface with tower wiring and base-located equipment, including one or more surge protection devices positioned to protect conductors at the tower base (110).

The TB-SPD (310) is depicted as part of a cable assembly that includes a coiled cable portion and opposing end portions that terminate at connectorized or terminated interfaces. In this configuration, the TB-SPD (310) is arranged to be coupled in-line with one or more electrical conductors such that surging energy on the conductors is shunted through one or more suppression elements of the TB-SPD (310) rather than being delivered to downstream equipment. The depicted end portions can include multiple conductor terminations that facilitate coupling the TB-SPD (310) between an upstream run (e.g., a run extending toward the tower top (105)) and a downstream run (e.g., a run extending toward equipment within or adjacent the base enclosure(s) (112)).

In FIG. 3B, the TB-SPD (310) is depicted as a packaged module having a housing and one or more electrical interfaces. The electrical interfaces can include one or more terminal blocks, multi-position connectors, or other field-wireable interfaces enabling the TB-SPD (310) to be installed at the tower base (110) and electrically coupled between tower wiring and base-located equipment. The TB-SPD (310) may include a plurality of protected channels within the housing, with each protected channel corresponding to a respective conductor pair or respective conductor set routed through the TB-SPD (310).

In some embodiments, the TB-SPD (310) includes a frequency-specific network configured to respond selectively to an assigned interrogation frequency on a shared pair of conductors, such that a monitoring unit can determine a location/identity of the TB-SPD (310) and an operational state of the TB-SPD (310) based on a returned signal characteristic. In such embodiments, the operational state can be represented by a multi-state response (including at least no-fault, degradation, and critical-failure states) using a returned signal magnitude that differs across the states.

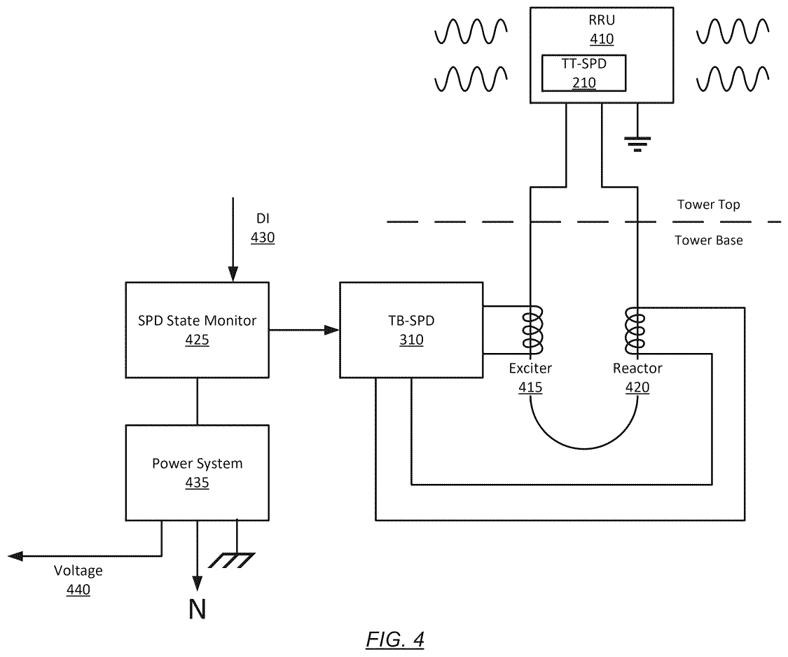

### Detailed Description—FIG. 4

(410) A remote radio unit (RRU) (410) is positioned at the tower top (105) and is coupled to one or more conductor paths routed along the tower (102) toward the tower base (110). In the illustrated arrangement, the RRU (410) is associated with a local ground reference at the tower top (105), and the conductor paths extend downward across the tower-top/tower-base boundary indicated in the figure.

(210) A tower-top surge protection device (TT-SPD) (210) is associated with the tower-top equipment and is shown disposed within the RRU (410). The TT-SPD (210) is electrically coupled to a conductor pair that extends along the tower (102), such that surge energy present on the conductor pair is shunted through surge suppression circuitry of the TT-SPD (210) rather than being delivered to circuitry of the RRU (410) or to downstream equipment.

(310) A tower-base surge protection device (TB-SPD) (310) is positioned at the tower base (110) and is coupled to the conductor pair routed along the tower (102) toward the RRU (410). The TB-SPD (310) is arranged such that the conductor pair is electrically associated with surge suppression circuitry of the TB-SPD (310) at the tower base (110), and the TB-SPD (310) is further arranged for cooperative operation with monitoring circuitry located at or near the tower base (110).

Referring now to FIG. 4, a functional block diagram of an enhanced surge protection system is shown according to illustrative embodiments. As shown, a tower-top surge protection device (TT-SPD) coupled with a remote radio unit (RRU), a TB-SPD, an exciter, a reactor, a power system, and an SPD state monitor.

An exciter (415) is disposed proximate to the conductor pair and is arranged as an electromagnetic coupling structure positioned to couple an interrogation signal onto the conductor pair without requiring a direct conductive connection. In operation, the exciter (415) is driven by a monitoring unit and couples energy into the conductor pair to establish a stimulus that propagates toward the tower top (105) and interacts with one or more frequency-selective structures associated with the TT-SPD (210) and/or the TB-SPD (310).

A reactor (420) is disposed proximate to the conductor pair and is arranged as an electromagnetic sensing structure positioned to sense a return signal associated with the conductor pair. The reactor (420) is positioned relative to the exciter (415) so that the reactor (420) senses signal characteristics on the conductor pair that result from interaction of the interrogation signal with impedance conditions presented by the TT-SPD (210), the TB-SPD (310), and the conductor run along the tower (102).

An SPD state monitor (425) is coupled to the exciter (415) and the reactor (420) and is configured to generate interrogation signals applied via the exciter (415) and to evaluate sensed return signals received via the reactor (420). In one implementation, the SPD state monitor (425) applies a sequence of interrogation frequencies and determines an identity and operating state of at least one SPD based on a frequency-dependent response and a return-signal magnitude detected on the conductor pair.

A device interface (DI) (430) is coupled to the SPD state monitor (425) and provides an output path for reporting monitoring results. The DI (430) can be used to convey an indication of SPD identity, an operating state classification, or an alarm condition to a downstream device, a network node, or a local user interface.

A power system (435) is coupled to the SPD state monitor (425) and provides operating power for the monitoring and interrogation functions. The power system (435) is shown coupled to a supply input and to a neutral reference, and the power system (435) may further be coupled to a ground reference at the tower base (110) to establish a defined reference potential for monitoring electronics.

A voltage input (440) provides a supply source to the power system (435). The supply source may be derived from site power infrastructure and may be routed into the base enclosure environment (112) for powering the SPD state monitor (425) and associated circuitry.

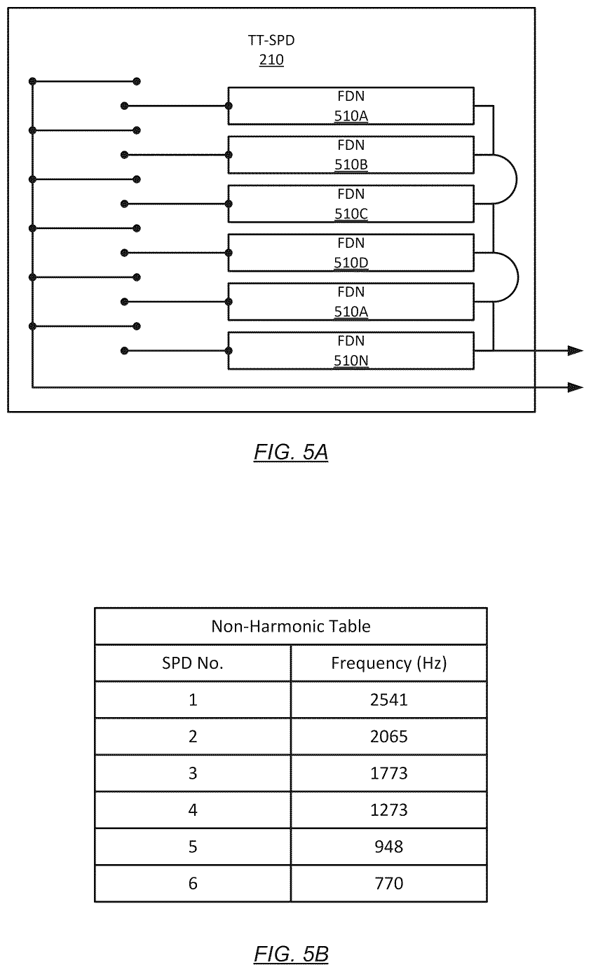

FIG. 5A shows the tower-top surge protection device (TT-SPD) (210) in which a plurality of internal channels is coupled to a shared external conductor path. In the illustrated configuration, multiple internal connection points of the TT-SPD (210) are routed toward a bank of frequency-selective elements, and an external conductor pair is shown extending from the TT-SPD (210) at an output side of the device.

A plurality of frequency determining networks (FDNs) (510A-510N) are disposed within the TT-SPD (210). Each FDN (510A-510N) is coupled to a corresponding internal connection point of the TT-SPD (210) and is arranged to present a frequency-dependent impedance response on the external conductor pair. In operation, different FDNs (510A-510N) are configured to respond differently to different interrogation frequencies, such that the TT-SPD (210) can exhibit distinguishable return characteristics as a function of the applied interrogation frequency.

The FDNs (510A-510N) are shown arranged in a parallel bank with respect to the external conductor pair, with each FDN (510A-510N) having an input side coupled to a respective internal node and an output side coupled to an output interface region. The output interface region is coupled to the external conductor pair indicated by the arrows at the right side of FIG. 5A, and the FDNs (510A-510N) thereby influence a signal observable on the external conductor pair when the TT-SPD (210) is interrogated at a corresponding frequency.

Each FDN (510A-510N) may be implemented using one or more passive circuit elements arranged to provide a selected frequency response, including a resonant response, a notch response, a bandpass response, or an impedance transition at a tuned frequency. In some embodiments, an FDN (510A-510N) is associated with a corresponding identifier such that, when the external conductor pair is driven at a frequency assigned to that identifier, the resulting return magnitude and/or return phase observed on the external conductor pair is distinguishable from return characteristics associated with other identifiers.

FIG. 5B illustrates a non-harmonic table that correlates an SPD number to a corresponding interrogation frequency. The table provides an example assignment in which SPD numbers 1-6 are mapped to respective frequencies 2541 Hz, 2065 Hz, 1773 Hz, 1273 Hz, 948 Hz, and 770 Hz. In use, the table is referenced by monitoring logic to select an interrogation frequency associated with a given SPD number, and the table can be stored as configuration data, derived from provisioning information, or otherwise made available to an SPD state monitor that interrogates the external conductor pair.

The SPD No. column represents a logical identifier usable to distinguish among multiple SPDs and/or multiple frequency-response channels. In some embodiments, the SPD number corresponds to an FDN (510A-510N) implemented in a given TT-SPD (210), while in other embodiments the SPD number corresponds to an SPD installed at a different physical location along the same conductor pair.

The Frequency (Hz) column represents interrogation frequencies selected to reduce harmonic overlap across the set of assigned frequencies. Although six example frequencies are shown, the table can include fewer or more frequencies, and the assigned frequencies can be adjusted to accommodate a desired number of SPDs, a desired frequency spacing, and expected conductor-path attenuation characteristics.

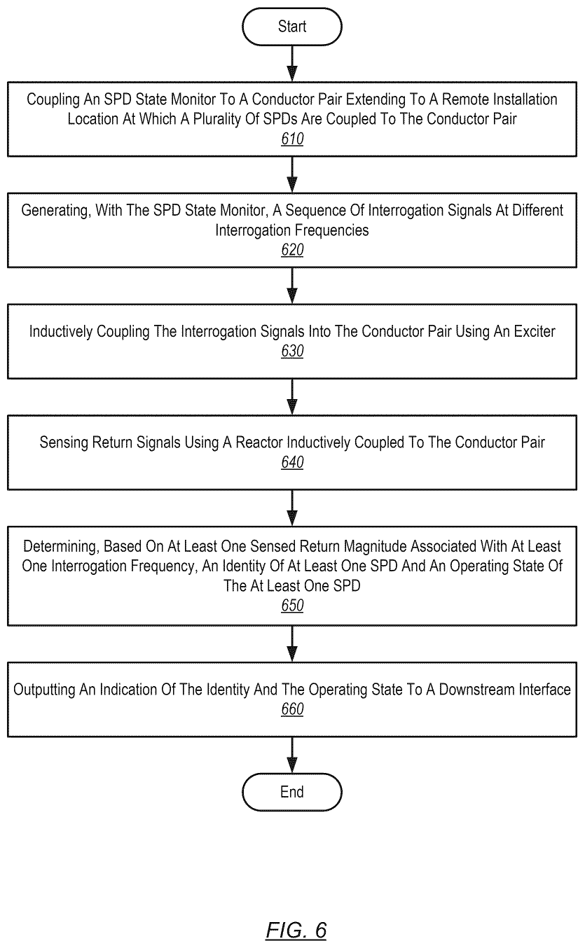

Referring now to FIG. 6, a method flowchart for remote SPD identification and state monitoring Is shown according to illustrative embodiments. The method of FIG. 6 can be implemented in one or more components of an enhanced surge protection system, such as the system shown in FIG. 4.

At Block 610, the process begins by establishing an electrical relationship between an SPD state monitor and a conductor pair that extends to a remote installation location. The conductor pair may be an existing wiring pair routed between a tower base and a tower top, or another conductor pair that traverses the remote location where multiple surge protection devices are installed. The conductor pair functions as the signaling medium for interrogation and return behavior used to infer the identity and operating state of one or more SPDs.

In implementation, the coupling step includes selecting the conductor pair to be monitored, establishing connectivity at a monitoring location (for example, at a tower base enclosure), and configuring the monitor with parameters associated with the conductor pair such as expected line length, attenuation characteristics, and any site-specific constraints. Where multiple SPDs are present on the same conductor pair, the monitor is configured to interpret multiple distinguishable responses corresponding to different SPD-associated frequency-selective networks.

At Block 620, the SPD state monitor generates a sequence of interrogation signals, each at a respective interrogation frequency, to probe the conductor pair and elicit frequency-dependent behavior from the installed SPDs. The interrogation signals may be generated as discrete tones, tone bursts, stepped-frequency sweeps, or other waveform formats that allow a return characteristic to be measured with sufficient resolution to distinguish among SPDs and among operating states.

To support configurations in which SPDs are assigned distinct frequencies, the monitor can step through a non-harmonic table that maps logical SPD identifiers to assigned interrogation frequencies. In one implementation, the monitor cycles through at least six interrogation frequencies including 2541 Hz, 2065 Hz, 1773 Hz, 1273 Hz, 948 Hz, and 770 Hz, while leaving the table extensible for additional SPDs or alternative frequency sets. The selected set may be chosen to reduce harmonic overlap and cross-coupling among channels so that returns attributable to different SPDs remain separable.

At Block 630, after selecting a given interrogation frequency, the interrogation signal is coupled into the conductor pair using an exciter that transfers energy electromagnetically rather than through a direct conductive connection. This coupling can be implemented with a coil or clamp-on coupler positioned around, adjacent to, or proximate the conductor pair so that the interrogation energy is injected onto the line while maintaining galvanic isolation between the monitoring electronics and the conductor pair.

In practice, the exciter coupling step can include setting a drive level suitable to produce a measurable return without materially disturbing other uses of the conductor pair and applying the signal for a defined dwell time sufficient to allow propagation and reflection from impedance features along the line. The monitor may also apply conditioning such as ramping the excitation amplitude, gating the injection window, or selecting a coupling mode that controls the frequency response of the injection path.

At Block 640, a reactor inductively senses return signals associated with the conductor pair. The return signals may include reflections or other line responses caused by impedance discontinuities created by frequency-selective networks associated with the SPDs, as well as changes in impedance caused by SPD operating state.

Implementation can include sampling the sensed signal in a measurement window aligned with the applied interrogation signal, filtering or demodulating around the active interrogation frequency, and extracting one or more metrics such as magnitude, phase, or a composite measure derived from the sensed waveform. The reactor coupling can be implemented similarly to the exciter coupling to maintain galvanic isolation and to reduce the likelihood that surge energy propagates into the monitor circuitry through a conductive path.

At Block 650, the monitor evaluates the sensed return for at least one interrogation frequency and determines which SPD is being indicated and what operating state applies. Identity determination may be performed by associating a frequency-specific response with the assigned interrogation frequency for a given SPD identifier, including cases where different SPDs on the same conductor pair present distinguishable return behavior at different assigned frequencies.

Operating state determination is performed by mapping a measured return characteristic to a defined state model. In one implementation, the monitor distinguishes at least a normal state associated with a first return magnitude, a degraded state associated with a second return magnitude different from the first, and a critical failure state associated with a short condition on the conductor pair. The short condition may be detected as a return signature consistent with a low-impedance condition that collapses or substantially overrides frequency-dependent behavior, thereby allowing the monitor to classify a critical failure even when the active interrogation frequency is varied.

At Block 660, once identity and operating state are determined, the monitor outputs an indication of the result to a downstream interface. The output can include the SPD identifier, the classified operating state, and optional associated data such as timestamp, confidence metric, return magnitude, or alarm severity encoding.

To support periodic monitoring, the monitor can repeat the sequence of interrogation signals at a predetermined interval, store, or update state information, and transmit the current state to a remote monitoring node via a communication interface. Transmission can be performed over a wired network, serial interface, or other site communication pathway, and can be integrated with alarm reporting so that changes from normal to degraded or from degraded to critical failure are propagated without requiring manual inspection at the remote installation location.

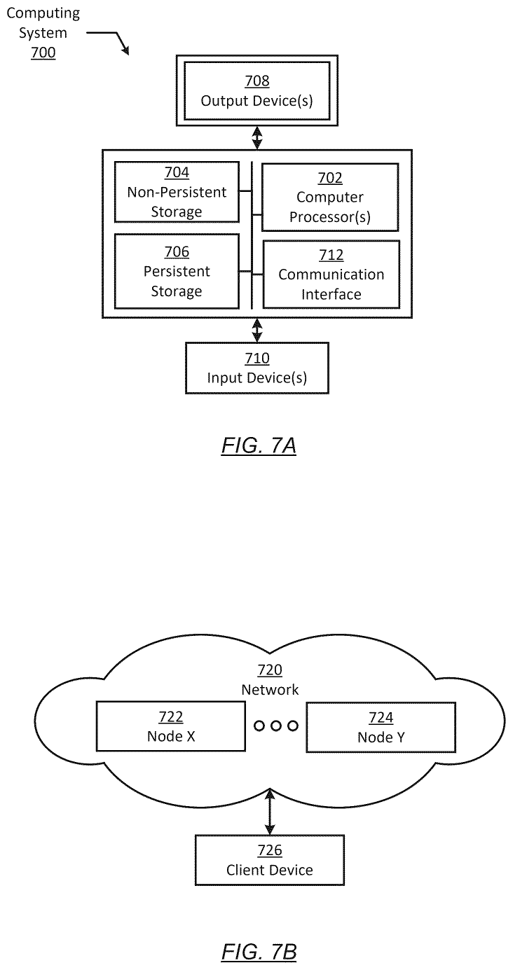

Embodiments may be implemented on a computing system specifically designed to achieve an improved technological result. When implemented in a computing system, the features and elements of the disclosure provide a significant technological advancement over computing systems that do not implement the features and elements of the disclosure. Any combination of mobile, desktop, server, router, switch, embedded device, or other types of hardware may be improved by including the features and elements described in the disclosure. For example, as shown in FIG. 7A, the computing system (700) may include one or more computer processors (702), non-persistent storage (704), persistent storage (706), a communication interface (712) (e.g., Bluetooth interface, infrared interface, network interface, optical interface, etc.), and numerous other elements and functionalities that implement the features and elements of the disclosure. The computer processor(s) (702) may be an integrated circuit for processing instructions. The computer processor(s) may be one or more cores or micro-cores of a processor. The computer processor(s) (702) includes one or more processors. The one or more processors may include a central processing unit (CPU), a graphics processing unit (GPU), a tensor processing unit (TPU), combinations thereof, etc.

The input devices (710) may include a touchscreen, keyboard, mouse, microphone, touchpad, electronic pen, or any other type of input device. The input devices (710) may receive inputs from a user that are responsive to data and messages presented by the output devices (708). The inputs may include text input, audio input, video input, etc., which may be processed and transmitted by the computing system (700) in accordance with the disclosure. The communication interface (712) may include an integrated circuit for connecting the computing system (700) to a network (not shown) (e.g., a local area network (LAN), a wide area network (WAN) such as the Internet, mobile network, or any other type of network) and/or to another device, such as another computing device.

Further, the output devices (708) may include a display device, a printer, external storage, or any other output device. One or more of the output devices may be the same or different from the input device(s). The input and output device(s) may be locally or remotely connected to the computer processor(s) (702). Many different types of computing systems exist, and the aforementioned input and output device(s) may take other forms. The output devices (708) may display data and messages that are transmitted and received by the computing system (700). The data and messages may include text, audio, video, etc., and include the data and messages described above in the other figures of the disclosure.

Software instructions in the form of computer readable program code to perform embodiments may be stored, in whole or in part, temporarily or permanently, on a non-transitory computer readable medium such as a CD, DVD, storage device, a diskette, a tape, flash memory, physical memory, or any other computer readable storage medium. Specifically, the software instructions may correspond to computer readable program code that, when executed by a processor(s), is configured to perform one or more embodiments of the invention, which may include transmitting, receiving, presenting, and displaying data and messages described in the other figures of the disclosure.

The computing system (700) in FIG. 7A may be connected to or be a part of a network. For example, as shown in FIG. 7B, the network (720) may include multiple nodes (e.g., node X (722), node Y (724)). Each node may correspond to a computing system, such as the computing system shown in FIG. 7A, or a group of nodes combined may correspond to the computing system shown in FIG. 7A. By way of an example, embodiments may be implemented on a node of a distributed system that is connected to other nodes. By way of another example, embodiments may be implemented on a distributed computing system having multiple nodes, where each portion may be located on a different node within the distributed computing system. Further, one or more elements of the aforementioned computing system (700) may be located at a remote location and connected to the other elements over a network.

The nodes (e.g., node X (722), node Y (724)) in the network (720) may be configured to provide services for a client device (726), including receiving requests and transmitting responses to the client device (726). For example, the nodes may be part of a cloud computing system. The client device (726) may be a computing system, such as the computing system shown in FIG. 7A. Further, the client device (726) may include and/or perform all or a portion of one or more embodiments of the invention.

The computing system of FIG. 7A may include functionality to present raw and/or processed data, such as results of comparisons and other processing. For example, presenting data may be accomplished through various presenting methods. Specifically, data may be presented by being displayed in a user interface, transmitted to a different computing system, and stored. The user interface may include a GUI that displays information on a display device. The GUI may include various GUI widgets that organize what data is shown as well as how data is presented to a user. Furthermore, the GUI may present data directly to the user, e.g., data presented as actual data values through text, or rendered by the computing device into a visual representation of the data, such as through visualizing a data model.

Thus, the illustrative embodiments described herein provide systems, devices, and methods for remotely determining identity and operating state of surge protection devices deployed at remote installation locations. The techniques described herein are applicable to installations in which surge protection is distributed across physically separated locations and coupled by one or more conductor paths routed between the locations. Interrogation signals may be applied to a conductor path at a monitoring location and return behavior may be sensed to obtain information associated with one or more surge protection devices coupled to the conductor path, including deployments in which multiple surge protection devices are associated with a shared conductor pair.

Remote identification and state determination are supported by frequency-selective behavior implemented at, or associated with, a surge protection device. Different devices, or different channels within a device, may be configured to present distinguishable impedance responses as a function of interrogation frequency, enabling an interrogation process to correlate a sensed response with a device identity. Operating state determination may be based on one or more metrics derived from the sensed return behavior, including metrics representative of magnitude, phase, or other characteristics attributable to impedance conditions along the conductor path, and state determination may support a multi-state model including conditions indicative of normal operation, degradation, or failure.

Coupling between monitoring electronics and the conductor path is implemented using electromagnetic coupling to provide galvanic isolation while still enabling injection and sensing of interrogation signals. Monitoring results may be output through one or more interfaces to downstream equipment, such as local monitoring devices, network nodes, or remote systems, and the interrogation process may be performed on a scheduled, periodic, or event-driven basis. The disclosed configurations are not limited to a particular site topology, housing form factor, surge suppression element, frequency plan, or communication pathway, and may be adapted to different conductor types, different numbers of surge protection devices, and different operating environments.

As used herein, the term “connected to” contemplates multiple meanings. A connection may be direct or indirect (e.g., through another component or network). A connection may be wired or wireless. A connection may be temporary, permanent, or semi-permanent communication channel between two entities.

The various descriptions of the figures may be combined and may include or be included within the features described in the other figures of the application. The various elements, systems, components, and steps shown in the figures may be omitted, repeated, combined, and/or altered as shown from the figures. Accordingly, the scope of the present disclosure should not be considered limited to the specific arrangements shown in the figures.

In the application, ordinal numbers (e.g., first, second, third, etc.) may be used as an adjective for an element (i.e., any noun in the application). The use of ordinal numbers is not to imply or create any particular ordering of the elements nor to limit any element to being only a single element unless expressly disclosed, such as by the use of the terms “before”, “after”, “single”, and other such terminology. Rather, the use of ordinal numbers is to distinguish between the elements. By way of an example, a first element is distinct from a second element, and the first element may encompass more than one element and succeed (or precede) the second element in an ordering of elements.

Further, unless expressly stated otherwise, the term “or” is an “inclusive or” and, as such includes the term “and.” Further, items joined by the term “or” may include any combination of the items with any number of each item unless, expressly stated otherwise.

In the above description, numerous specific details are set forth in order to provide a more thorough understanding of the disclosure. However, it will be apparent to one of ordinary skill in the art that the technology may be practiced without these specific details. In other instances, well-known features have not been described in detail to avoid unnecessarily complicating the description. Further, other embodiments not explicitly described above can be devised which do not depart from the scope of the claims as disclosed herein. Accordingly, the scope should be limited only by the attached claims.

What is claimed is:

1. An enhanced surge protection system, comprising:
an SPD state monitor configured to couple to a conductor pair extending to a remote installation location;
an exciter positioned to electromagnetically couple an interrogation signal into the conductor pair;
a reactor positioned to electromagnetically sense a return signal associated with the conductor pair;
a plurality of surge protection devices (SPDs) coupled to the conductor pair at the remote installation location, wherein different SPDs of the plurality of SPDs include corresponding frequency-selective networks that present different impedance responses as a function of interrogation frequency; and
wherein the SPD state monitor is configured to:
apply a plurality of interrogation frequencies via the exciter,
sense, via the reactor, corresponding return signals, and
determine, based on at least one of the interrogation frequencies and a return-signal magnitude, an identity and an operating state of at least one SPD of the plurality of SPDs.

2. The system of claim 1, wherein the exciter and the reactor are galvanically isolated from the conductor pair and are each inductively coupled to the conductor pair.

3. The system of claim 1, wherein the plurality of interrogation frequencies is selectively orthogonal and non-harmonic with respect to each other.

4. The system of claim 1, wherein, at the remote installation location, the frequency-selective networks of the plurality of SPDs are coupled to the conductor pair in parallel.

5. The system of claim 1, wherein the SPD state monitor is configured to determine at least three operating states for a given SPD based on the return signal, including:
a first state associated with a first return-signal magnitude,
a second state associated with a second return-signal magnitude different than the first return-signal magnitude, and
a third state associated with a short condition on the conductor pair.

6. The system of claim 5, wherein the third state comprises a critical failure state in which the given SPD is configured to short the conductor pair such that the return signal is substantially independent of the interrogation frequency.

7. The system of claim 1, further comprising a device interface (DI) coupled to the SPD state monitor, wherein the SPD state monitor is configured to output, via the DI, an indication of the identity and the operating state of the at least one SPD.

8. The system of claim 1, further comprising a power system configured to provide a supply voltage to at least the SPD state monitor.

9. The system of claim 1, wherein the remote installation location is a cell site including a tower having a tower top and a tower base, and wherein the plurality of SPDs includes a tower-top surge protection device (TT-SPD) disposed at the tower top and a tower-base surge protection device (TB-SPD) disposed at the tower base.

10. The system of claim 9, wherein the cell site includes a remote radio unit (RRU) at the tower top, and wherein the TT-SPD is disposed in a top enclosure associated with the RRU and the TB-SPD is disposed in a base enclosure at the tower base.

11. A surge protection device (SPD) for use in a frequency-interrogated surge protection system, the SPD comprising:
a set of terminals configured to couple to a conductor pair;
a surge suppression stage coupled to the terminals;
a frequency-selective network coupled to the terminals and configured to present, at a selected interrogation frequency assigned to the SPD, a first impedance different than a second impedance presented at at least one other interrogation frequency; and
a state-encoding circuit configured to alter, responsive to a condition of the surge suppression stage, a return characteristic presented to the conductor pair such that an SPD state monitor coupled to the conductor pair can distinguish at least two operating states of the SPD based on a sensed return magnitude.

12. The SPD of claim 11, wherein the surge suppression stage includes a primary MOV and a secondary MOV coupled in parallel.

13. The SPD of claim 12, wherein the secondary MOV is dissimilarly rated relative to the primary MOV such that the secondary MOV is configured to fail before the primary MOV under repeated surge exposure, thereby indicating a degraded state of the SPD.

14. The SPD of claim 12, further comprising at least one solder-flag failure mechanism coupled to at least one of the primary MOV or the secondary MOV.

15. The SPD of claim 11, wherein the frequency-selective network comprises a plurality of frequency determining networks (FDNs) configured to provide different frequency responses corresponding to different assigned interrogation frequencies.

16. A method for remotely identifying and monitoring surge protection devices, comprising:
coupling an SPD state monitor to a conductor pair extending to a remote installation location at which a plurality of SPDs is coupled to the conductor pair;
generating, with the SPD state monitor, a sequence of interrogation signals at different interrogation frequencies;
inductively coupling the interrogation signals into the conductor pair using an exciter;
sensing return signals using a reactor inductively coupled to the conductor pair;
determining, based on at least one sensed return magnitude associated with at least one interrogation frequency, an identity of at least one SPD and an operating state of the at least one SPD; and
outputting an indication of the identity and the operating state to a downstream interface.

17. The method of claim 16, wherein generating the sequence of interrogation signals comprises stepping through a non-harmonic table of interrogation frequencies.

18. The method of claim 17, wherein the non-harmonic table comprises at least six interrogation frequencies including 2541 Hz, 2065 Hz, 1773 Hz, 1273 Hz, 948 Hz, and 770 Hz.

19. The method of claim 16, wherein determining the operating state comprises distinguishing:
a normal state associated with a first return magnitude,
a degraded state associated with a second return magnitude,
a critical failure state associated with a short condition on the conductor pair.

20. The method of claim 16, further comprising repeating the sequence of interrogation signals at a predetermined interval, and transmitting the identity and operating state to a remote monitoring node via a communication interface.
